(19) United States
(12) Patent Application Publication
(10) Pub. No.: US 2022/0076858 A1
(43) Pub. Date: Mar. 10, 2022

(54) FLEXIBLE CONDUCTIVE THIN FILM BASED ON SILVER POWDER AND PDMS, AND PREPARATION METHOD THEREFOR

(71) Applicant: SHENZHEN INSTITUTES OF ADVANCED TECHNOLOGY CHINESE ACADEMY OF SCIENCES, Guangdong (CN)

(72) Inventors: Hui LI, Guangdong (CN); Jinjie ZHANG, Guangdong (CN); Lei WANG, Guangdong (CN)

(73) Assignee: SHENZHEN INSTITUTES OF ADVANCED TECHNOLOGY CHINESE ACADEMY OF SCIENCES, Guangdong (CN)

(21) Appl. No.: 17/413,292

(22) PCT Filed: Apr. 10, 2019
(86) PCT No.: PCT/CN2019/082154

§ 371 Date: Jun. 11, 2021

(51) Int. Cl. H01B 1/22; H01L 21/288

(52) U.S. Cl. CPC H01B 1/22; H01L 21/288

(57) ABSTRACT

The invention applies to the technical field of the flexible conductive film and provides a stretchable and super-sensitive flexible conductive film based on silver powder and PDMS and its manufacturing method. The manufacturing method comprises the following steps: preparing silver powder, PDMS prepolymer, and the said PDMS curing agent; after the said silver powder is ground, cleaned, and dried, adding the said PDMS prepolymer for even mixing, and then adding the said PDMS curing agent for mixing to get the liquid flexible conductive film; spin-coating the said liquid flexible conductive film to a certain thickness and get the flexible conductive film after curing. The flexible conductive film comprises silver powder and PDMS film substrate, wherein the said powder silver is evenly distributed within the said PDMS film substrate. The invention provides a flexible conductive film based on silver powder and PDMS and its manufacturing method, whose manufacturing processes are simple and free of hazardous chemical reagents, raising lower requirements for the device but performing well in conductivity and stretchability.

### FIELD OF THE INVENTION

The invention falls under the technical field of the flexible conductive film, especially involving a flexible conductive film based on silver powder and PDMS and its manufacturing method.

### BACKGROUND TECHNOLOGY

Along with the development and progress of science and technology, flexible electronics and wearable electronic devices show great market prospects; nearly all major consumer electronics companies all over the world have launched their own wearable products, especially those with physiological functions, which have attracted lots of attention. Since such products work on human beings' complex and irregular skin surfaces, the sensing technologies of wearable devices should be flexible and bio-compatible enough to avoid adverse reactions on human bodies. Obviously, traditional rigid substrate sensor does not mechanically match with human beings' complex three-dimensional skin surfaces, thus affecting user experience and measuring results. The development of electronic technologies and materials science has expedited the invention of flexible sensors meeting the above requirements.

Currently, the stretchable flexible conductive film based on silver powder and PDMS is mainly manufactured by means of the following methods:

1. Add the mixture of 48.5 g styrene (ST), 1.5 g divinylbenzene (DVB), and 2.0 g azobisisobutyronitrile (AIBN) to a 500 mL four-neck round-bottom flask in which there are 2 g polyvinylpyrrolidone (PV P), 135 g ethanol, and 15 g water, place the said flask in oil bath where the temperature is maintained at 70° C. The mixture is deoxidized through nitrogen bubbling, and stirred at the same time. After 24 hours, take the flask out of the oil bath, and cool it down in the air. Deionized water is adopted for centrifugalizing and purifying the obtained crosslinked polystyrene/silver powder (PS@Ag) microspheres several times. Mix the PDMS prepolymer and PDMS curing agent, and add the prepared core-shell PS@Ag filler to mix for 5 minutes at a speed of 2,000 rpm. Then, get the mixture degassed for 10 minutes in the vacuum, pour the sticky mixture into the mold and get it scraped to prepare the conductive film, or adopt the manual screen printing method to directly print it on the substrate for getting various conductive patterns. After that, get it heated for 4 hours at 80° C. for curing.

2. Mix the PDMS prepolymer and PDMS curing agent (Sylgard®184). Then, add benzophenone (with a weight ratio of 3%) and silver powder (with a volume ratio of 17%-22%) into the PDMS mixture and get it degassed for 15 minutes. Spin-coat the prepared PDMS-Ag photoresist mixture onto the flexible substrate (such as polyester or silicone) for 30 seconds. Load the spin-coated chip to a site with a distance of 50 pitches from the optical mask. After being irradiated by 12 mW/cm ultraviolet for 10 minutes, conduct 50-second exposure under 120 heavy doses of ultraviolet irradiation (it is necessary to apply a dose of 7,200 mJ/cm to induce a complete photochemical reaction of silver particles under significant light transmission attenuation) for baking. In the post-exposure baking period, the unexposed region is fully crosslinked, while the exposed region remains uncured. Place the uncured PDMS into methylbenzene for 5 seconds to get it removed. After the development, get it flushed with 2-propanol and dried with nitrogen flow. Get the patterns prepared on the flexible substrate laminated or the oxygen plasma bonded for forming multi-layer devices. Finally, get the micro-processed devices molded into anticipated shapes for biomedical purposes via thermal compression steps.

3. Get PDMS prepolymer and PDMS curing agent mixed. After degassing, pour the mixed solution into a round mold to prepare a stretchable substrate. Get the mixed solution in the mold cured for 1 hour at a constant temperature of 60° C., thus forming a PDMS substrate with a thickness of 300. Tear off the cured PDMS substrate from the round substrate, and cut the PDMS substrate into a rectangle whose dimensions are 4×2.5 cm². In order to manufacture PDMS substrate with wave-shaped patterns, get both ends of the rectangle PDMS substrate fastened at the substrate support, and pull both ends of PDMS substrate until the required pre-strain conditions are met. Then, expose the surface of the pre-strained PDMS substrate to UVO for 30 minutes. After UVO processing, release the pre-strained PDMS substrate at a speed of 1 mm/sec to form wave-shaped patterns on the PDMS substrate. In order to manufacture smooth and bendable PDMS substrate with wave-shaped patterns, get the PDMS substrate fasted on the substrate support with a constant pre-strain of 20%, and also increase the time of UVO processing to 40-60 minutes. DC reactive magnetron sputtering (DC sputtering) is conducted on the translucent silver (Ag) film on PDMS substrate with wave-shaped patterns. Use a DC sputtering system to deposit the translucent Ag film of different thicknesses (10, 15, and 20 nm) on flat PDMS substrate with wave-shaped patterns. During the DC reactive magnetron sputtering process, the PDMS substrate rotates at a constant speed of 20 rpm at ambient temperature. The translucent Ag film grows under a constant DC reactive power of 100 W, working pressure of 2 mTorr, and an Ar flow rate of 20 sccm (standard ml/min).

Although the flexible conductive film manufactured based on the above method is somewhat conductive and stretchable, there're still some deficiencies:

1. The manufacturing processes are complex, and the conductive material, namely, the silver powder, shall be preprocessed in a complicated way so that the surface of the silver powder will be modified

2. The manufacturing processes involve hazardous chemical reagents to human bodies, including styrene, divinylbenzene, azobisisobutyronitrile, and benzophenone;

3. Advanced manufacturing devices are required, such as DC reactive magnetron sputtering;

4. Flexible conductive film manufactured based on the above method is weak in conductivity and stretchability.

### SUMMARY OF THE INVENTION

### Technical Issues

The invention aims to solve at least one of the above technical issues, and provides a flexible conductive film based on silver powder and PDMS and its manufacturing method, whose manufacturing processes are simple and free of hazardous chemical reagents, raising lower requirements for the device but performing well in conductivity and stretchability.

### Solutions to Technical Issues

### Technical Solutions

The invention involves the following technical solution: A manufacturing method of the flexible conductive film based on silver powder and PDMS, comprising the following steps: the silver powder, PDMS prepolymer, and PDMS curing agent should be prepared, wherein the said silver powder has a diameter less than 12 μm;

After the said silver powder is ground, cleaned, and dried, add the said PDMS prepolymer for even mixing and add the said PDMS curing agent to get the liquid flexible conductive film;

The said liquid flexible conductive film is spin-coated to a preset thickness and cured to get the flexible conductive film.

Optionally, the cleaning steps comprise:

5-10 g ethanol is added to the container with silver powder, and the mixture of silver powder and ethanol is dispersed through an ultrasonic machine;

After the said silver powder is deposited at the bottom of the said container, the ethanol above the silver power is evaporated to remove the remaining ethanol.

Optionally, the said silver powder has a diameter within 2-3.5 μm.

Optionally, the weight ratio between the said silver powder and the said PDMS film substrate is within 150 wt. %-200 wt. %.

Optionally, the weight ratio between the said PDMS prepolymer and the said PDMS curing agent is 10:1.

Optionally, the said liquid flexible conductive film comprises the following curing methods:

The said well-mixed liquid flexible conductive film is placed onto the silicon chip and spin-coated onto the spin coater for forming the to-be-cured film, and the spin-coating speed of the spin coater is 400-1,000 rpm with a spin-coating time of 15-25 s;

The said to-be-cured film and the said silicon chip are placed onto the heating plate and heated for 15-30 minutes at 60-100° C.; the said to-be-cured film then forms a cured flexible conductive film; after the said silicon chip and the said flexible conductive film cool down, the said flexible conductive film is then removed from the said silicon chip.

The embodiment of the invention also provides a flexible conductive film based on silver powder and PDMS, comprising silver powder and PDMS film substrate, wherein the said silver powder is evenly distributed within the said PDMS film substrate, and the said silver powder has a diameter less than 12 μm.

Optionally, the said silver powder has a diameter within 2-3.5 μm.

Optionally, the weight ratio between the said silver powder and the said PDMS film substrate is within 150 wt. %-200 wt. %.

### Beneficial Effects of the Invention

### Beneficial Effects

The invention provides a flexible conductive film based on silver powder and PDMS, whose form can be arbitrarily stretched, bent and twisted, making it possible to fit well with any curved surface; PDMS film substrate is bio-compatible, nontoxic, and conformable with skin, and can be widely applied to wearable devices due to its high sensitivity and good effects. The manufacturing processes are simpler and faster, which eliminate the use of dangerous chemical reagents like strong acids and strong alkalis and any high-precision and high-tech device. Moreover, the experimental results also prove that the flexible conductive film manufactured in this invention has a sensitivity coefficient of up to 939, which is much higher than similar finished products.

### BRIEF DESCRIPTION OF FIGURES

### Description of Figures

In order to specify the technical solution involved in the embodiment of the invention more clearly, relevant figures required will be described.

Obviously, the figures below just present some embodiments of the invention; ordinary technicians in this technical field may also obtain other figures based on these ones without creative work.

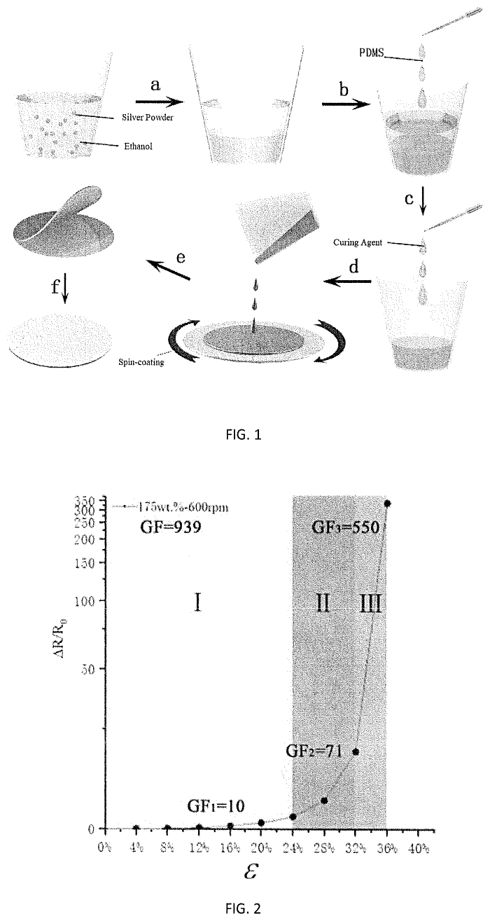

FIG. 1 presents the schematic diagram of the manufacturing method of the flexible conductive film used based on silver powder and PDMS in the embodiment of the invention for reference;

FIG. 2 presents GF values of the flexible conductive film based on silver powder and PDMS provided in the embodiment of the invention during different stages of the stretching process.

### EMBODIMENTS OF THE INVENTION

### Detailed Description

In order to present the objects, technical solutions, and advantages of the invention in a more clear way, the invention is further detailed in combination with the appended drawings and embodiments below. It should be understood that specific embodiments described herein just serve the purpose of explaining the invention instead of imposing restrictions on it.

Specific technical features and embodiments described in the specific implementation ways can be combined in an appropriate way without arousing conflicts. For instance, the combination of different specific technical features/embodiments can help to form different implementation ways. The combination ways of specific technical features/embodiments will not be otherwise elaborated so as to avoid undesired repetition.

### Embodiment I

Embodiment I provides the manufacturing method of a flexible conductive film based on silver powder and PDMS, comprising the following steps: silver powder, polydimethylsiloxane (PDMS) prepolymer and PDMS curing agent are prepared, and the said silver powder has a diameter less than 12 μm to guarantee sensitivity;

After the said silver powder is ground, cleaned, and dried, add the said PDMS prepolymer for even mixing and then add the said PDMS curing agent to get the well-mixed liquid flexible conductive film. After two mixings, PDMS is well-mixed, and the silver powder is distributed in a more even way, thus getting a flexible conductive film with higher sensing accuracy;

The said liquid flexible conductive film is evenly spin-coated to a preset thickness and cured to get the flexible conductive film. The manufacturing method is simpler and faster, which eliminates the use of dangerous chemical reagents like strong acids and strong alkalis and any high-precision and high-tech device, with low manufacturing costs and good effects.

Specifically, the cleaning steps comprise:

5-10 g ethanol is added to the container with silver powder, and the mixture of silver powder and ethanol is dispersed through an ultrasonic machine;

After the said silver powder is deposited at the bottom of the said container, the ethanol above the silver power is evaporated to remove the remaining ethanol.

Preferably, the silver powder has a diameter of 1.5-5 μm; in this embodiment, the said silver powder has a diameter of 2-3.5 μm.

Specifically, the weight ratio between the said silver powder and the said PDMS film substrate is within 150 wt. %-200 wt. %.

Specifically, the weight ratio between the said PDMS prepolymer and the said PDMS curing agent is 10:1.

Specifically, the said liquid flexible conductive film comprises the following curing methods:

The said well-mixed liquid flexible conductive film is placed onto the silicon chip and spin-coated onto the spin coater for forming the to-be-cured film, and the spin-coating speed of the spin coater is 400-1,000 rpm with a spin-coating time of 15-25 s; the silicon chip can be pre-sprayed with a release agent.

Put the said to-be-cured film and silicon chip onto the heating plate and get them heated for 15-30 minutes at 60-100° C.; the said to-be-cured film then forms the cured flexible conductive film; after the said silicon chip and flexible conductive film cool down, the said flexible conductive film is released from the said silicon chip; with highly-flexible PDMS as the substrate material, the evenly-distributed silver powder is mixed to get Ag/PDMS film through ultrasonic dispersion, mixing, spin-coating, heating, and curing. By controlling the weight ratio of silver powder to PDMS substrate, as well as the speed and time of spin-coating, the flexible conductive film with different characteristics is obtained.

To solve the problems of the current flexible conductive film manufacturing method, such as complex manufacturing processes, high requirements for manufacturing devices, the use of too many chemical reagents hazardous to human bodies, and inadequate stretchability and conductivity, Embodiment I provides a simple and fast manufacturing method of a flexible conductive film based on silver powder and PDNS during which no dangerous chemical reagents like strong acids and strong alkalis and any high-precision and high-tech device are required. By controlling the weight ratio between silver powder and PDMS and the speed and time of spin-coating, the conductivity and thickness of the flexible conductive film can be controlled, which satisfies different application needs. The flexible conductive film with a larger weight ratio and a greater spin-coating speed can be applied to flexible sensors with low sensitivity and large measuring scope. In contrast, the flexible conductive film with a small weight ratio and a slow spin-coating speed can be used for flexible sensors that require high sensitivity and small measuring scope.

In the specific embodiments, please refer to FIG. 1 for the preparation processes of the flexible conductive film.

(a): Silver powder (with a diameter of 2-3.5 μm and a purity of over 99.9%) is preprocessed; that is to say, the silver powder is ground in the mortar to refine the caked silver powder. Later, the ground silver powder is transferred into a container, and 5-10 g ethanol is added to the said container. Finally, the mixed solution of silver powder and ethanol is dispersed for 15-30 minutes through the ultrasonic machine, waiting for the silver powder to deposit at the bottom of the container.

(b): First of all, remove the ethanol solution floating above the silver powder in the container with a straw. Then, after the ethanol fully evaporates (at ambient temperature), add PDMS prepolymer to the container (the weight ratio between silver powder and PDMS is within 150 wt. %-200 wt. %. When the weight ratio is less than 150 wt. %, the film has poor conductivity; when the weight ratio is greater than 200 wt. %, the mixture of silver powder and PDMS is quite sticky, which is not conducive to uniform spin-coating on the silicon chip). After that, the mixture of silver powder and PDMS is mixed in a planetary mixer for 3-5 minutes at a speed of 2,000-2,200 rpm, which aims to disperse the silver powder in the PDMS substrate more evenly to get a well-mixed mixture.

(c): Add PDMS curing agent (the weight ratio between PDMS prepolymer and curing agent is 10:1) to the said mixture, and get it mixed again in the planetary mixer for 1.5-3 minutes at a speed of 2,000-2,200 rpm so that the curing agent is fully mixed with PDMS prepolymer.

(d): Pour the said mixture onto the silicon chip for spin-coating on the spin coater. In this step, the speed and time of spin-coating can be changed to control the thickness of the film. In Embodiment II, the spin-coating speed is within 400-1,000 rpm, while the spin-coating time is within 15-25 s.

(e): Place the evenly spin-coated film and the silicon chip onto the heating plate, and get them heated for 15-30 minutes at 60-100° C. Later, after the silicon chip and the film cool down (at ambient temperature), remove the flexible conductive film from the silicon chip easily.

(f): The flexible conductive film is released from the silicon chip to get the film based on silver powder and PDMS.

A tensile test is conducted on the flexible conductive film by measuring the initial resistance and initial length of the flexible conductive film and the resistance and length of the stretched film. In the specific embodiments, a resistance measuring device (such as SMU SourceMeter) can be connected to the flexible conductive film through wires. Clamp both ends of the flexible conductive film with the clamps of the stretching device, gradually stretch the flexible conductive film with the help of the stretching device, and record the resistance values at different stretching degrees until the flexible conductive film breaks and lapses. FIG. 2 shows GF values of the flexible conductive film during different stages of the stretching process, with an overall GF value of 939.

In this embodiment of the invention, the above tensile test results prove that the flexible conductive film has good conductivity and stretchability, with a maximum elongation of 48% and a maximum sensitivity (GF) of 939, wherein gauge factor (GF) is the strain sensitivity coefficient, defined as GF=[(R−R₀)/R₀]/[(L−L₀)/L₀]. R₀ and R represent the initial resistance and resistance after the stretch of the flexible conductive film; L₀ and L represent the initial length and the length after the stretch of the flexible conductive film. This embodiment of the invention provides a flexible conductive film based on silver powder and its manufacturing method; the simpler and faster manufacturing processes eliminate the use of dangerous chemical reagents like strong acids and strong alkalis and any high-precision and high-tech device. Moreover, the experimental results also prove that the silver power/PDMS film (flexible conductive film) manufactured in this invention has a sensitivity coefficient of up to 939, which is much higher than similar finished products.

### Embodiment II

Embodiment II provides a flexible conductive film based on silver powder and PDMS, which can be manufactured based on the method provided in Embodiment I and used for the sensors of wearable device, comprising silver powder and PDMS film substrate, wherein PDMS is short for polydimethylsiloxane, odorless and highly transparent, with high stretchability, thermal resistance and cold resistance, whose viscosity varies little with temperature. The said silver powder is evenly distributed within the said PDMS film substrate, and the said silver powder has a diameter less than 12 μm; with excellent conductivity, its μm-level size can guarantee the sensitivity of the flexible conductive film. Since the silver powder is evenly distributed within the said PDMS film substrate and the substrate is deformable arbitrarily, when the flexible conductive film deforms subjected to an external force, local distance and local density of the silver powder at the deformation site will change, thus leading a change in the resistance of the flexible conductive film, as well as a change in the current flowing through the film and/or a change in the voltage applied onto the film, endowing it with high sensitivity (supersensitivity).

Specifically, the said silver powder has a diameter of fewer than 10 μm. For instance, the silver powder has a diameter within 1-6 μm to guarantee its sensitivity.

Specifically, the said silver powder has a diameter within 1-4.5 μm; preferably, the diameter of the silver powder can be within 2-3.5 μm.

Specifically, the weight ratio between the said silver powder and the said PDMS film substrate is within 100 wt. %-300 wt. %.

In Embodiment II, the weight ratio between the said silver powder and the said PDMS film substrate is within 150 wt. %-200 wt. %. When the weight ratio is less than 150 wt. %, the film has poor conductivity; when the weight ratio is greater than 200 wt. %, the mixture of silver powder and PDMS is quite sticky, which is not conducive to subsequent uniform spin-coating, so its formability will be poor.

In specific embodiments, conductive electrodes can be inserted, affixed, or fastened to both sides of the PDMS film substrate. Conductive electrodes can be connected to the resistance measuring device.

In specific embodiments, a flexible protective layer can be set on the surface of the PDMS film substrate, which should be wear-resistant, tear-resistant, and corrosion-resistant, such as silicon protective layer, etc.

In the specific embodiments, PDMS film substrate is polygonal (rectangle, triangle), round, cylindrical, etc.

In this embodiment of the invention, the above tensile test results prove that the flexible conductive film has good conductivity and stretchability, with a maximum elongation of 48% and a maximum sensitivity (GF) of 939, wherein gauge factor (GF) is the strain sensitivity coefficient, defined as GF=[(R−R₀)/R₀]/[(L−L₀)/L₀], namely, GF is obtained by dividing [(L−L₀)/L₀] with [(R−R₀)/R₀]. R₀ and R represent the initial resistance and resistance after the stretch of the flexible conductive film; L₀ and L represent the initial length and the length after the stretch of the flexible conductive film. This embodiment of the invention provides a flexible conductive film based on silver powder and its manufacturing method; the simpler and faster manufacturing processes eliminate the use of dangerous chemical reagents like strong acids and strong alkalis and any high-precision and high-tech device. Moreover, the experimental results also prove that the silver power/PDMS film (flexible conductive film) manufactured in this invention has a sensitivity coefficient of up to 939, which is much higher than similar finished products.

In the specific embodiments, the above flexible conductive film (PDMS film substrate) has a thickness of 0.05-5 mm or other appropriate thickness. For example, the above flexible conductive film has a thickness of 0.1-2 mm.

Embodiment II provides a flexible conductive film based on silver powder and PDMS, whose form can be arbitrarily stretched, bent and twisted, making it possible to fit well with any curved surface; PDMS film substrate is bio-compatible, nontoxic, and conformable with skin, and can be widely applied to wearable devices due to its high sensitivity and good effects.

The said embodiments just represent the best embodiments of this invention, but do not serve the purpose of restricting this invention; any revision, equivalent replacement, or improvement made within the spirit and principle of this invention is included in the protection scope of this invention.

1. A manufacturing method of the flexible conductive film based on silver powder and PDMS, characterized in that the silver powder, PDMS prepolymer and PDMS curing agent shall be manufactured and that the said silver powder has a diameter less than 12 μm;
After the said silver powder is ground, cleaned, and dried, add the said PDMS prepolymer for even mixing and add the said PDMS curing agent to get the liquid flexible conductive film;
The said liquid flexible conductive film is spin-coated to a preset thickness and cured to get the flexible conductive film.

2. The said manufacturing method of the flexible conductive film based on silver powder and PDMS as claimed in claim 1, characterized in that the cleaning steps comprise: adding 5-10 g ethanol to the container with silver powder and dispersing the mixture of silver powder and ethanol with an ultrasonic machine;
After the said silver powder is deposited at the bottom of the said container, the ethanol above the silver power is evaporated to remove the remaining ethanol.

3. The said manufacturing method of the flexible conductive film based on silver powder and PDMS as claimed in claim 1, characterized in that the said silver powder has a diameter of 2-3.5 μm.

4. The said manufacturing method of the flexible conductive film based on silver powder and PDMS, as claimed in claim 1, characterized in that the weight ratio between the said silver powder and the said PDMS film substrate is within 150 wt. %-200 wt. %.

5. The said manufacturing method of the flexible conductive film based on silver powder and PDMS as claimed in claim 1, characterized in that the weight ratio between the said PDMS prepolymer and the said PDMS curing agent is 10:1.

6. The manufacturing method of claim 1, wherein, said liquid flexible conductive film has the following curing steps:
The said well-mixed liquid flexible conductive film is placed onto the silicon chip and spin-coated onto the spin coater for forming the to-be-cured film, and the spin-coating speed of the spin coater is 400-1,000 rpm with a spin-coating time of 15-25 s;
The said to-be-cured film and the said silicon chip are placed onto the heating plate and heated for 15-30 minutes at 60-100° C.; the said to-be-cured film then forms a cured flexible conductive film; after the said silicon chip and the said flexible conductive film cool down, the said flexible conductive film is then removed from the said silicon chip.

7. A flexible conductive film based on silver powder and PDMS, characterized in that it comprises silver powder and PDMS film substrate, that the said silver powder is evenly distributed within the said PDMS film substrate, and that the said silver powder has a diameter less than 12 μm.

8. The said flexible conductive film based on silver powder and PDMS as claimed in claim 7, characterized in that the said silver powder has a diameter of 2-3.5 μm.

9. The said flexible conductive film of claim 7, wherein the weight ratio between the said silver powder and the said PDMS film substrate is within 150 wt. %-200 wt. %.

10. The flexible conductive film of claim 8, wherein the weight ratio between the said silver powder and the said PDMS film substrate is within 150 wt. %-200 wt. %.
